(19) United States
(12) Patent Application Publication
(10) Pub. No.: US 2013/0188820 A1
(43) Pub. Date: Jul. 25, 2013

(54) RETRACTABLE HEADSET FOR MOBILE DEVICES

(71) Applicant: Tim McLaughlin, Vienna, VA (US)

(72) Inventor: Tim McLaughlin, Vienna, VA (US)

(73) Assignee: Headwire, LLC, Vienna, VA (US)

(21) Appl. No.: 13/354,477

(22) Filed: Jan. 20, 2012

(51) Int. Cl. H04R 1/10; H05K 5/00

(52) U.S. Cl. 381/384; 174/50

(57) ABSTRACT

In some embodiments, a retractable headset includes a housing, a retainer, a spring, and a wire. The housing configured to be coupled to a mobile device. The retainer is rotatably coupled to the housing and receives the spring and at least a portion to the wire. The wire is coiled with the spring such that at least a portion of the wire engages at least a portion of the spring when in a first configuration. The wire is configured to rotate the retainer when moved from the first configuration to a second configuration. An end of the wire is coupled to an audio plug that is removably coupled to the housing.

### BACKGROUND

The embodiments described herein relate to headsets. More particularly, the embodiments described herein relate to retractable headsets for mounting to mobile devices, such as, for example, mobile phones.

Hands-free communication associated with the use of mobile devices is well known. Often, hands-free communication is desirable for mobile telephone users who wish to perform other tasks while using the mobile telephone, such as, for example, driving. Hands-free devices can generally be classified into two categories, wired and wireless.

Wired hands-free devices often include a long and cumbersome cord (wire) including an audio plug at one end and at least one earpiece and a second end. In some instances, the user has to manipulate hands-free device and/or the cord and store the device, when not in use, in a case, a bag, a purse, a pocket, etc. The storage of the hands-free device can lead to a limited availability when needed (e.g., when the user receives or wants to place a telephone call via the mobile device). Furthermore, improper or unsuitable storage can lead to a failure of the hands-free device (e.g., the cord breaks). Such difficulties have necessitated the development of retractable headsets allowing the user a degree of cord management.

Some known retractable headsets are coupled to the mobile device (e.g., by structure other than the audio plug). In such instances, the retractable headsets are bulky and require a secondary pouch or case to couple to the mobile device while storing the retractable headset. As the size of mobile device continues to the decrease, the increased size of a relatively large retractable headset can be undesirable. Furthermore, in some instances, the audio plug that couples to the audio jack of the mobile device can be in a fixed position such that the audio jack is inaccessible while the retractable headset is coupled to the mobile device. For example, in some instances, a user may utilize a retractable headset coupled to a mobile device and further wish to use the mobile device in conjunction with, for example, a car audio system (e.g., via an auxiliary port and the cars stereo system) to play music stored on the mobile device. In such instances, the user must remove the retractable headset from the mobile device to gain access to the audio jack. This process can be cumbersome and lead to the misplacement of the retractable headset.

In other instances, known retractable headsets are not coupled to the mobile device (e.g., by structure other than the audio plug). In such instances, storage of the retractable headset can still lead to a limited availability when needed. Furthermore, such known retractable headsets can be misplaced.

Known wireless hands-free devices include headsets that communicate with a mobile device via, for example, Bluetooth technology. In some instances, a user may be concerned with the potential health hazards of microwave radio signals associated with Bluetooth technology. In other instances, a user of a mobile device may desire a hands-free device but the mobile device is not compatible with Bluetooth technology. In still other instances, a user may be prone to misplacing small objects (e.g., Bluetooth headsets).

Thus, a need exists for improved retractable headsets that can be coupled to a mobile device.

### SUMMARY

Apparatus for a retractable headset for a mobile device are described herein. In some embodiments, a retractable headset includes a housing, a retainer, a spring, and a wire. The housing configured to be coupled to a mobile device. The retainer is rotatably coupled to the housing and receives the spring and at least a portion to the wire. The wire is coiled with the spring such that at least a portion of the wire engages at least a portion of the spring when in a first configuration. The wire is configured to rotate the retainer when moved from the first configuration to a second configuration. An end of the wire is coupled to an audio plug that is removably coupled to the housing.

### BRIEF DESCRIPTION OF THE DRAWINGS

FIG. 1 is a rear perspective view of a retractable headset in a first configuration, according to an embodiment.

FIG. 2 is a front perspective view of the retractable headset of FIG. 1, in a first configuration.

FIG. 3 is an exploded view of the retractable headset of FIG. 1.

FIG. 4 is a perspective view of a housing included in the retractable headset of

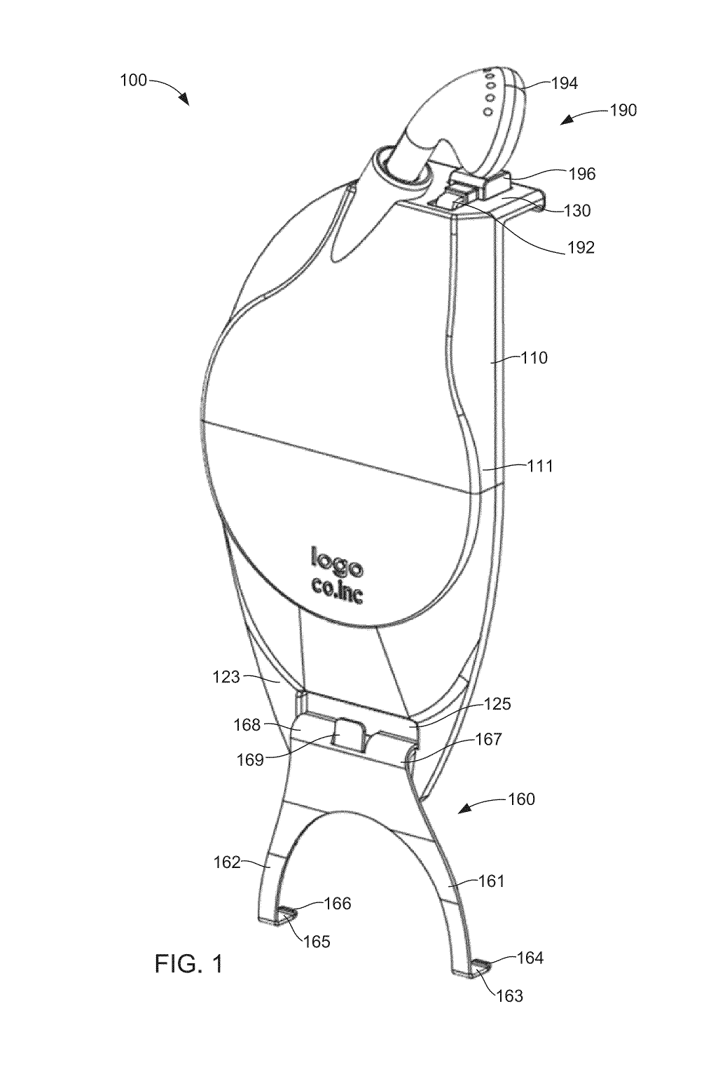

FIG. 1.

FIG. 5 is a perspective view of a portion of the retractable headset of FIG. 1.

FIG. 6 is a front perspective view of the retractable headset of FIG. 1, in a second configuration.

FIG. 7 is a perspective view of the retractable headset of FIG. 1 coupled to a mobile device.

FIG. 8 is a front perspective view of the retractable headset of FIG. 1 coupled to a mobile device, in the first configuration.

FIG. 9 is a front perspective view of the retractable headset of FIG. 1 coupled to a mobile device, in a third configuration.

FIG. 10 is a front perspective view of the retractable headset of FIG. 1 decoupled from a mobile device.

FIG. 11 is a rear perspective view of a retractable headset in a first configuration, according to an embodiment.

FIG. 12 is a perspective view of a housing included in the retractable headset of FIG. 11.

FIG. 13 is an exploded view of the retractable headset of FIG. 11.

FIG. 14 is a rear perspective view of a retractable headset in a first configuration, according to an embodiment.

FIG. 15 is a bottom perspective view of the retractable headset of FIG. 14.

FIG. 16 is an exploded view of the retractable headset of FIG. 14.

FIG. 17 is a perspective view of a retractable headset according to an embodiment.

FIG. 18 is an illustration of a wire assembly according to an embodiment.

### DETAILED DESCRIPTION

Apparatus for a retractable headset are described herein. In some embodiments, a retractable headset includes a housing, a retainer, a spring, and a wire. The housing configured to be coupled to a mobile device. The retainer is rotatably coupled to the housing and receives the spring and at least a portion to the wire. The wire is coiled with the spring such that at least a portion of the wire engages at least a portion of the spring when in a first configuration. The wire is configured to rotate the retainer when moved from the first configuration to a second configuration. An end of the wire is coupled to an audio plug that is removably coupled to the housing.

In some embodiments, a retractable headset includes a housing, a retraction mechanism, and a headset. The housing includes a first portion, configured to be coupled to a body of a mobile device, and a second portion, configured to be coupled to an audio jack of the mobile device. The second portion is configured to be removably or pivotally coupled to the first portion. The retraction mechanism includes a retainer, a spring, and a cover and is coupled to the housing. The cover is configured to maintain the spring within the retainer. A headset wire

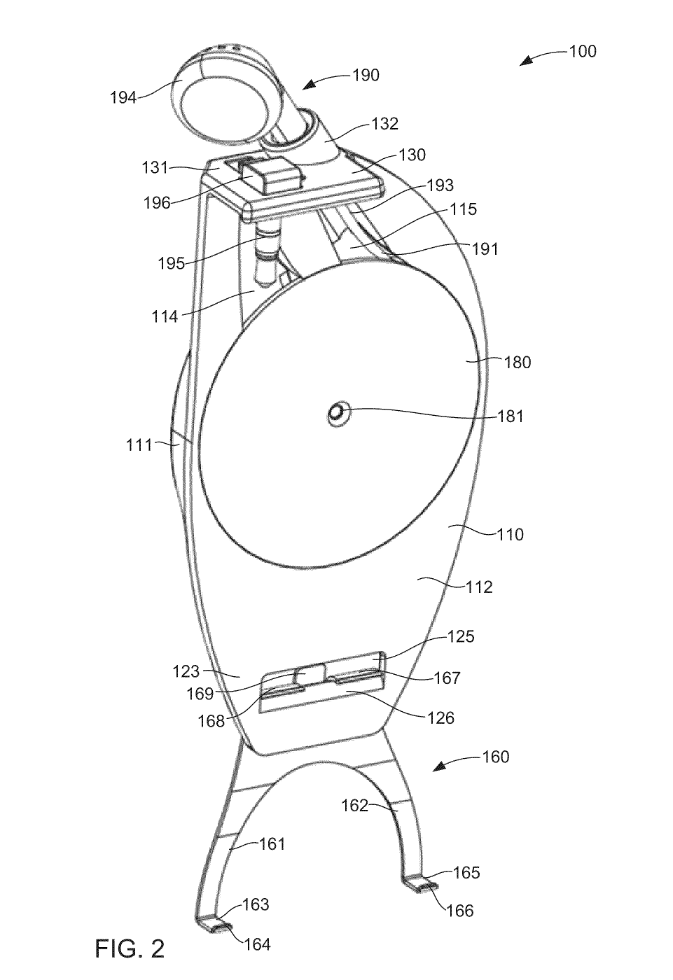

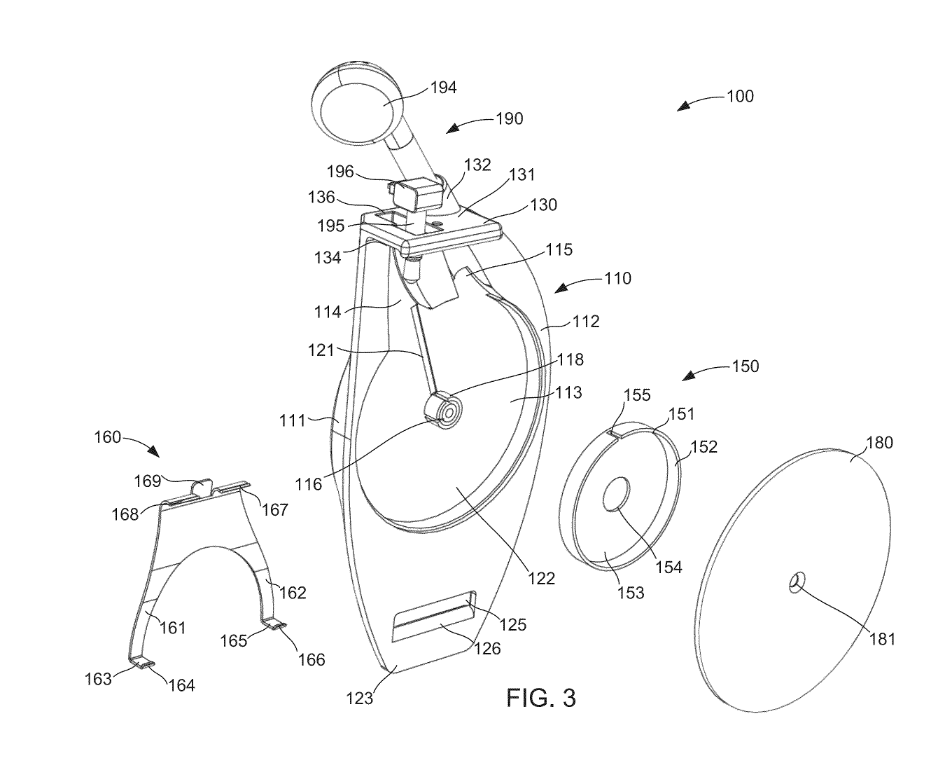

FIGS. 1 and 2 are perspective views of a retractable headset 100 according to an embodiment. The retractable headset 100 includes a housing 110, a retraction mechanism 150 (FIGS. 3 and 5), and a wire assembly 190 (FIG. 5). The housing 110 is configured to be coupled to a mobile device M (FIGS. 7-10), such as, for example, a smart phone. In some embodiments, the housing 110 can be configured to be coupled to an iPhone. The housing 110 can be any suitable size, shape, or configuration. For example, as shown in FIG. 1, the housing 110 can define a substantially oblong shape. Furthermore, the housing 110 can define a relatively small thickness such that, when coupled to the mobile device M, the mobile device M and the retractable headset 100 collectively define a relatively thin profile (e.g., thickness).

The housing 110 includes an upper latch portion 130 and defines a lower latch aperture 125. The upper latch portion 130 includes an aperture 136, configured to receive a first end portion 192 of a wire 191 included in the wire assembly 190, and a port 132, configured to receive a second end portion 192 of the wire 191 of the wire assembly 190. In this manner, the upper latch portion 130 can be coupled to a portion of the mobile device M, as described in further detail herein.

The lower latch aperture 125 is configured to receive a portion of a lower latch 160. More specifically, the lower latch 160 includes a first attachment arm 167, a second attachment arm 168, and an engagement portion 169. The first attachment arm 167 and the second attachment arm 168 can be disposed within the lower latch aperture 125 defined by the housing 110. Furthermore, the first attachment arm 167 and the second attachment arm 168 are disposed on an engagement surface 126 of the housing 110. The engagement surface 126 is a substantially arcuate surface configured to engage a surface of the first attachment arm 167 and the second attachment arm 168. The engagement portion 169 is a tab extending from a surface of the lower latch 160. The arrangement of the engagement surface 126, the first attachment arm 167, and the second attachment arm 168 is such that a user can engage the engagement portion 169 and press in a direction towards the housing 110. In this manner, the first attachment arm 167 and the second attachment arm 168 can slide along the engagement surface 126, as described in further detail herein.

The lower latch 160 further includes a first latch arm 161 and a second latch arm 162 extending substantially away from the first attachment arm 167 and the second attachment arm 168, respectively. The first latch arm 161 and the second latch arm 162 collectively engage a portion of the mobile device M to couple a bottom portion 123 of the housing 110 to a portion the mobile device M. More specifically, the first latch arm 161 includes a base 163 and a protrusion 164 configured to engage the portion of the mobile device M. Similarly, the second latch arm 162 includes a base 165 and a protrusion 166 configured to engage the portion of the mobile device M. In this manner, the protrusion 164 of the first latch arm 161 and the protrusion 166 of the second latch arm 162 can engage a surface of the mobile device M such that the protrusion 164 and the protrusion 166 maintain the lower latch 160 in contact with the mobile device M.

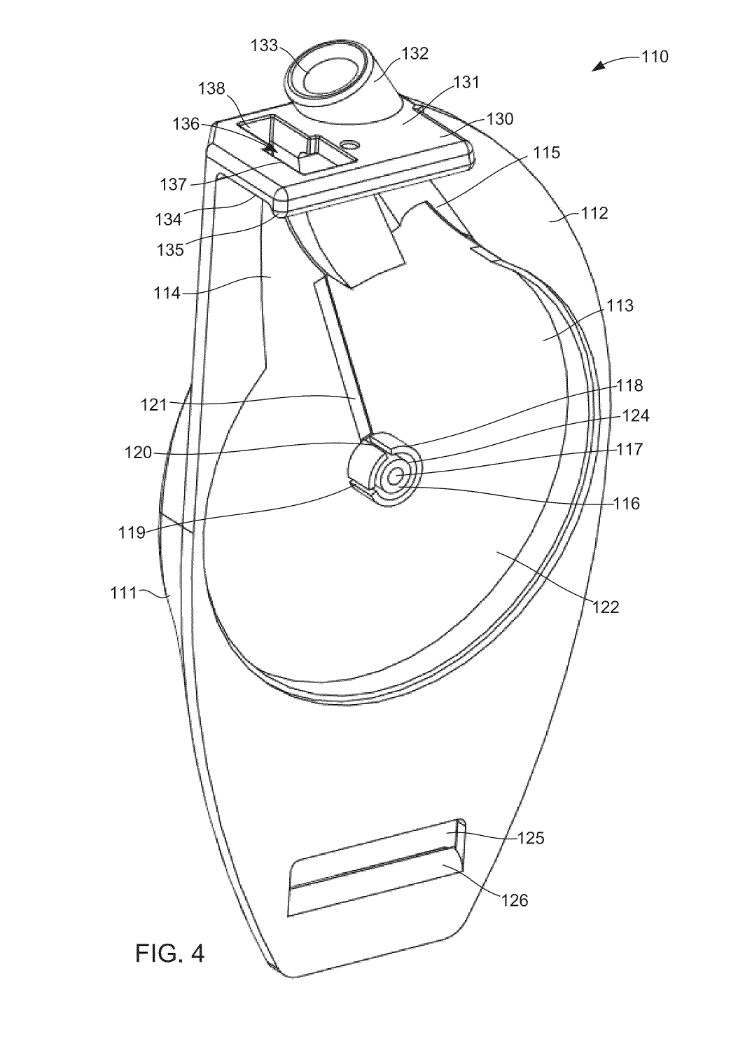

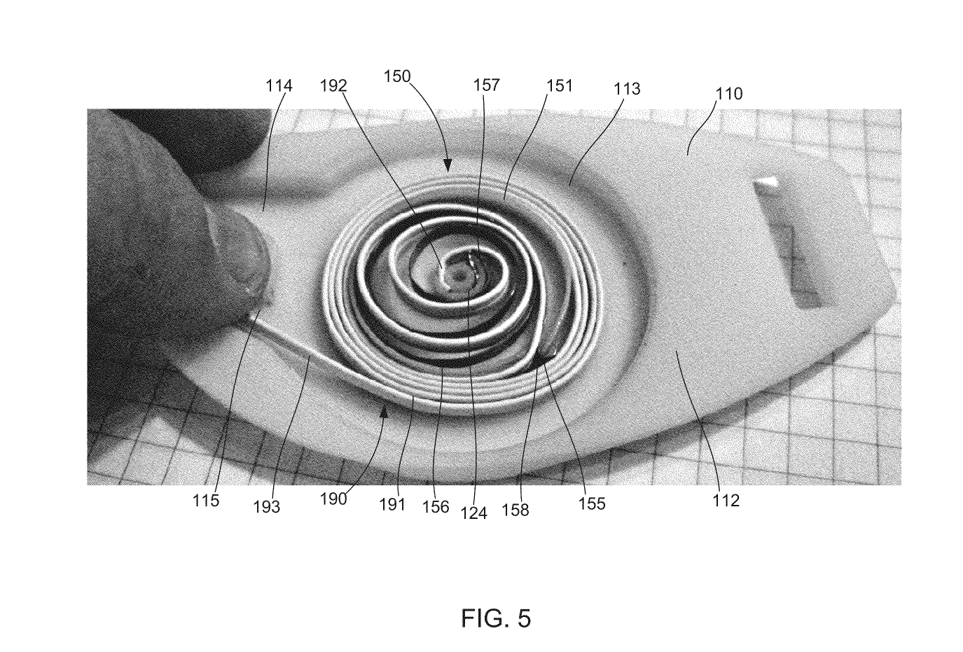

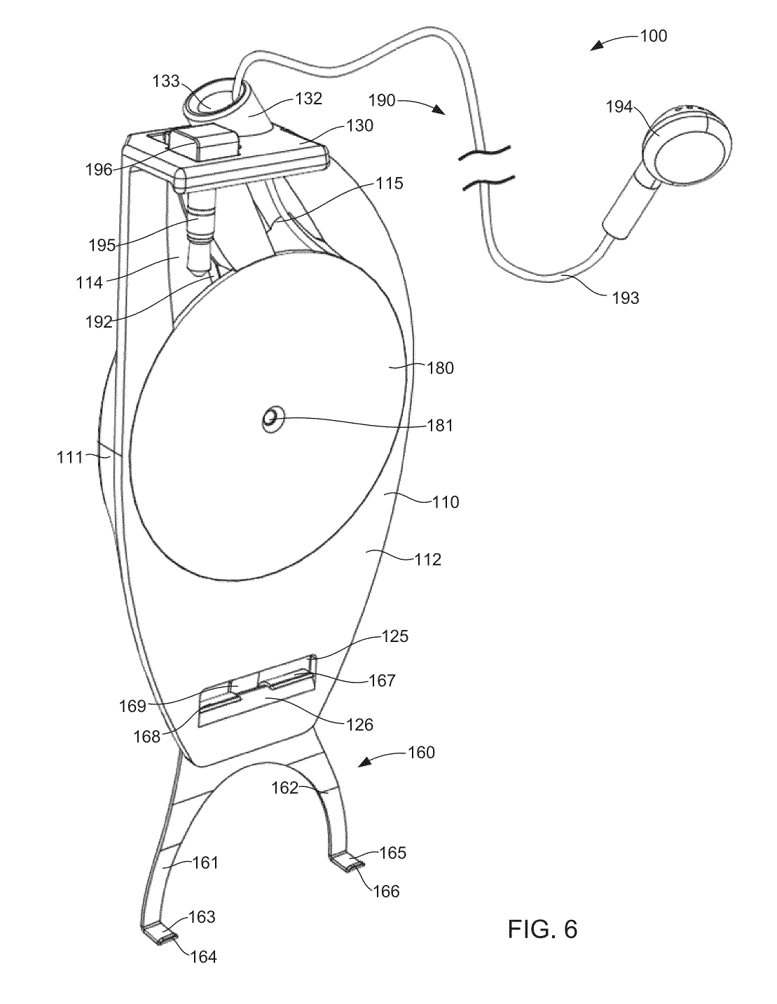

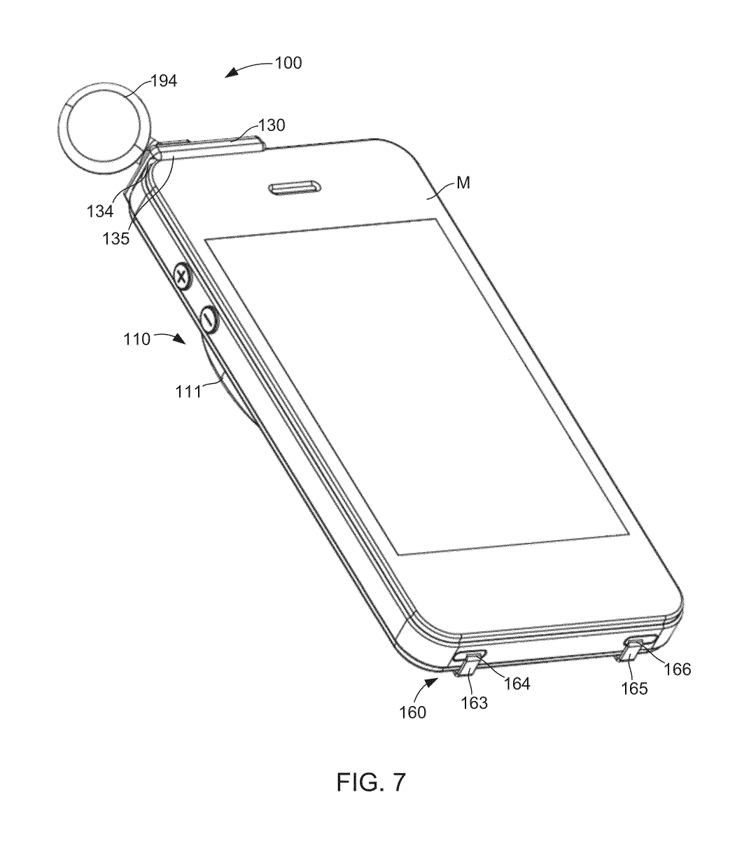

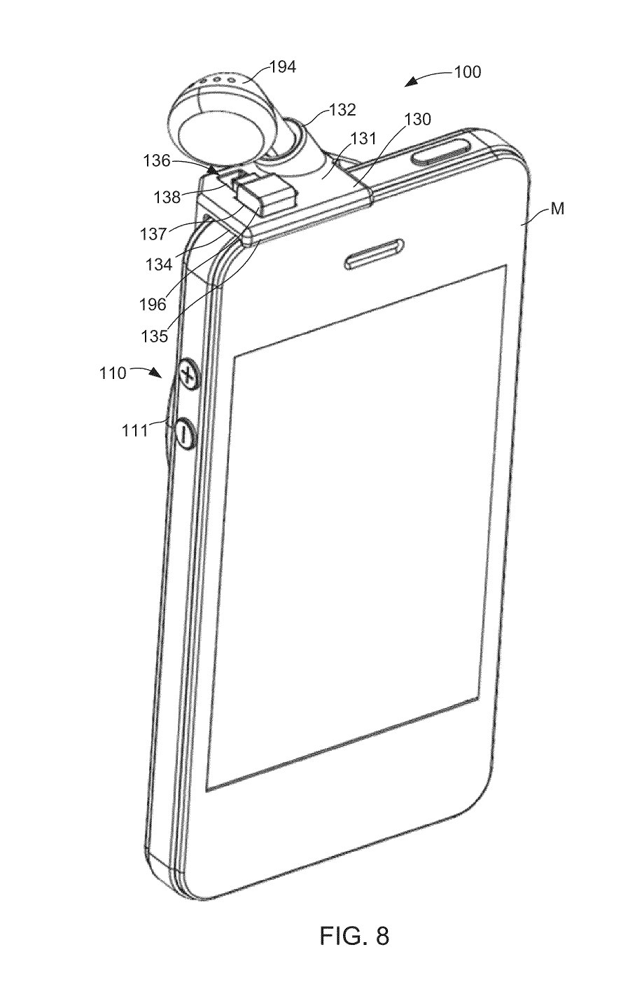

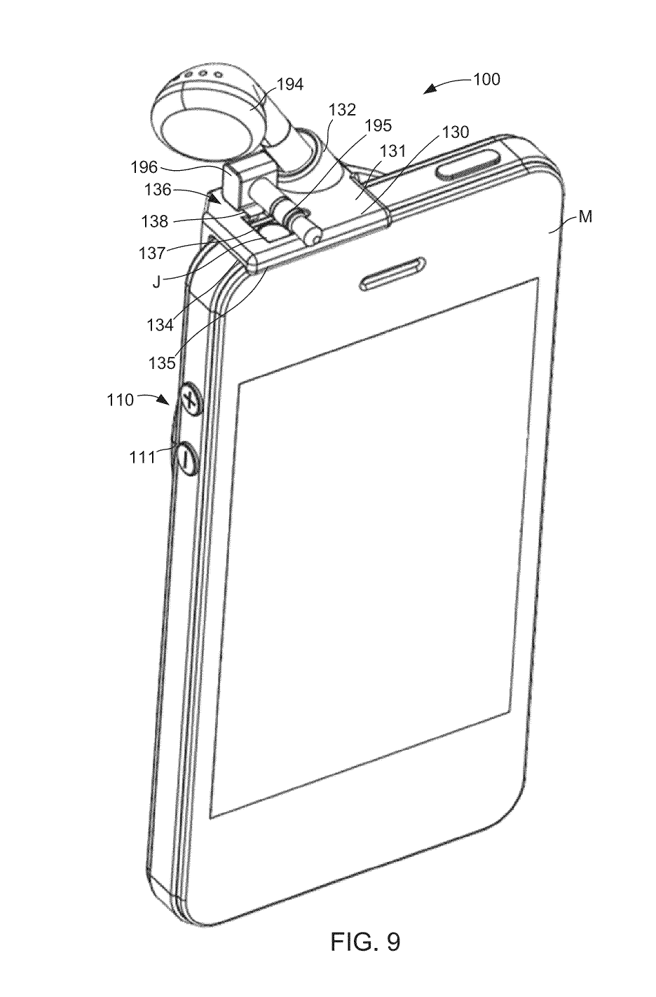

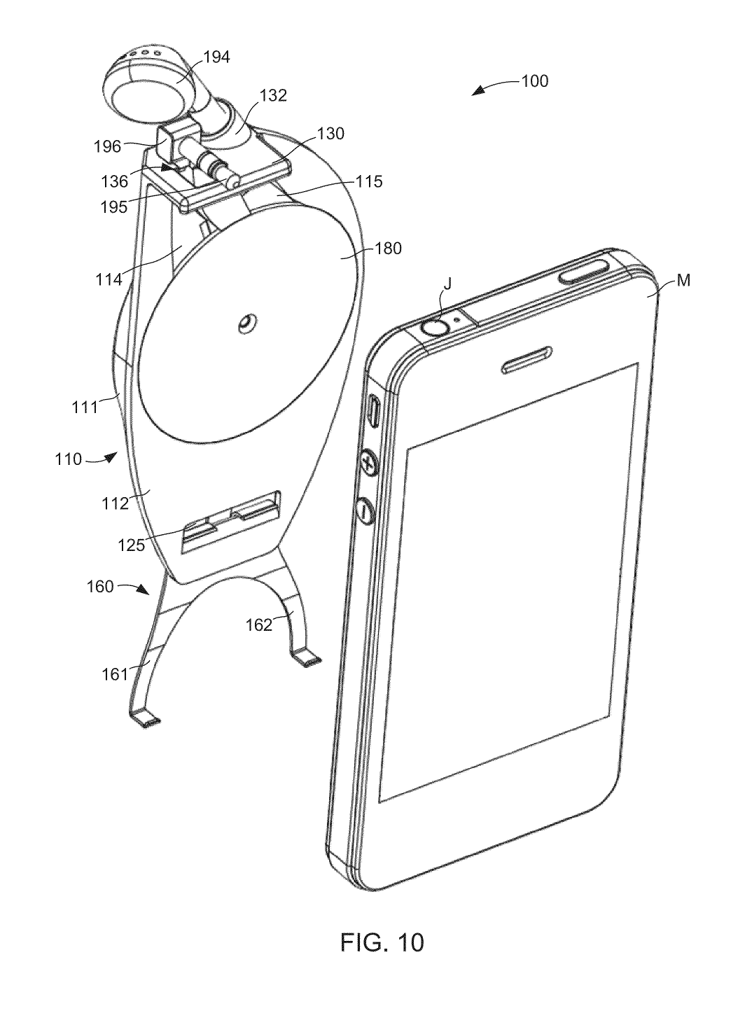

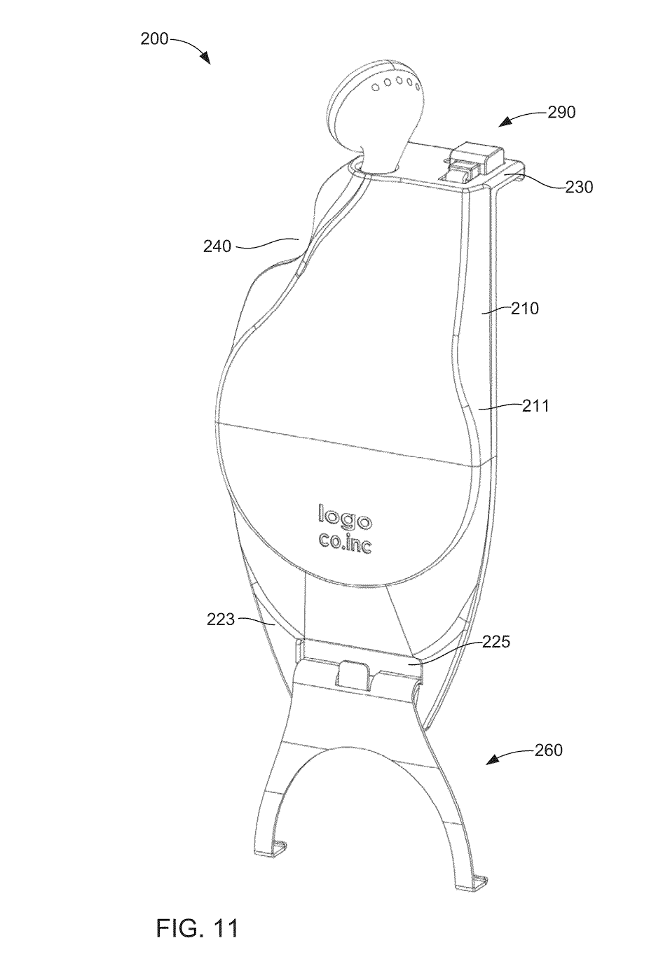

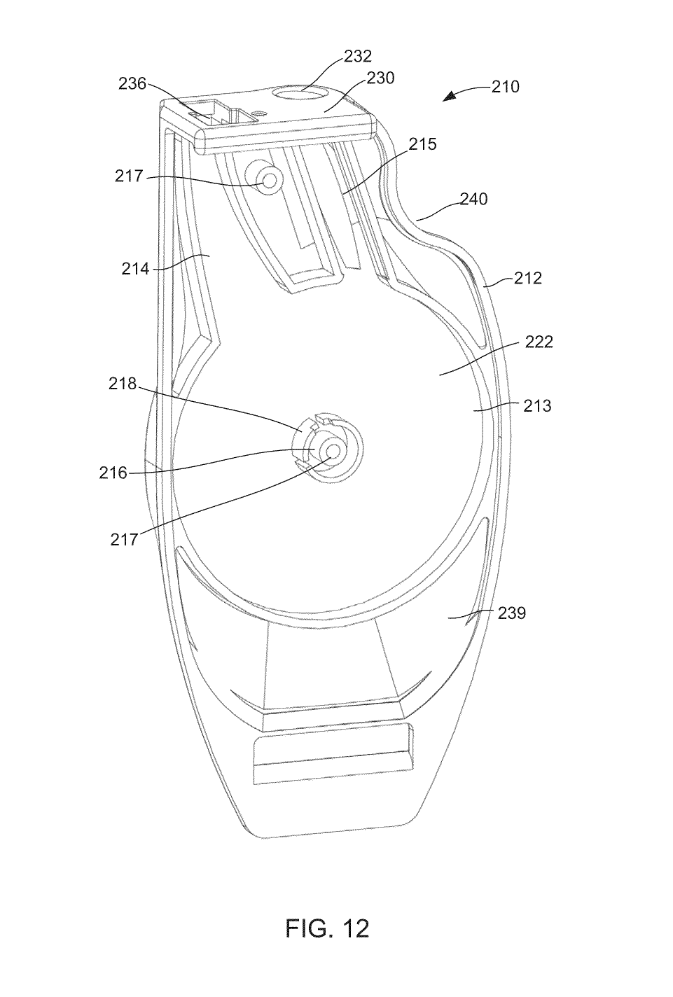

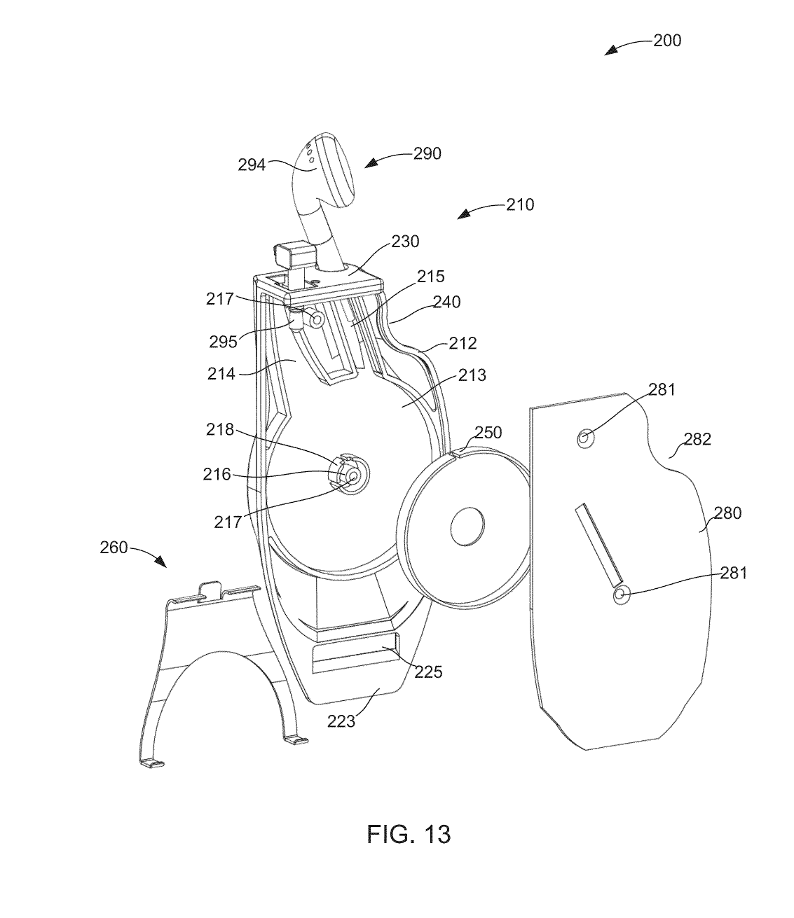

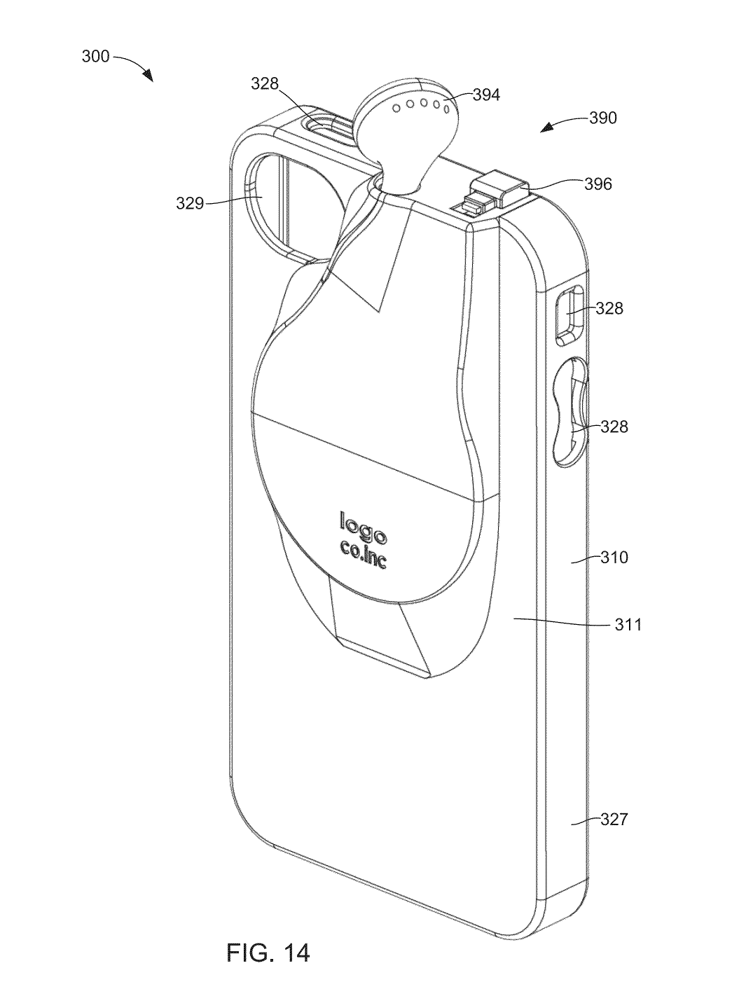

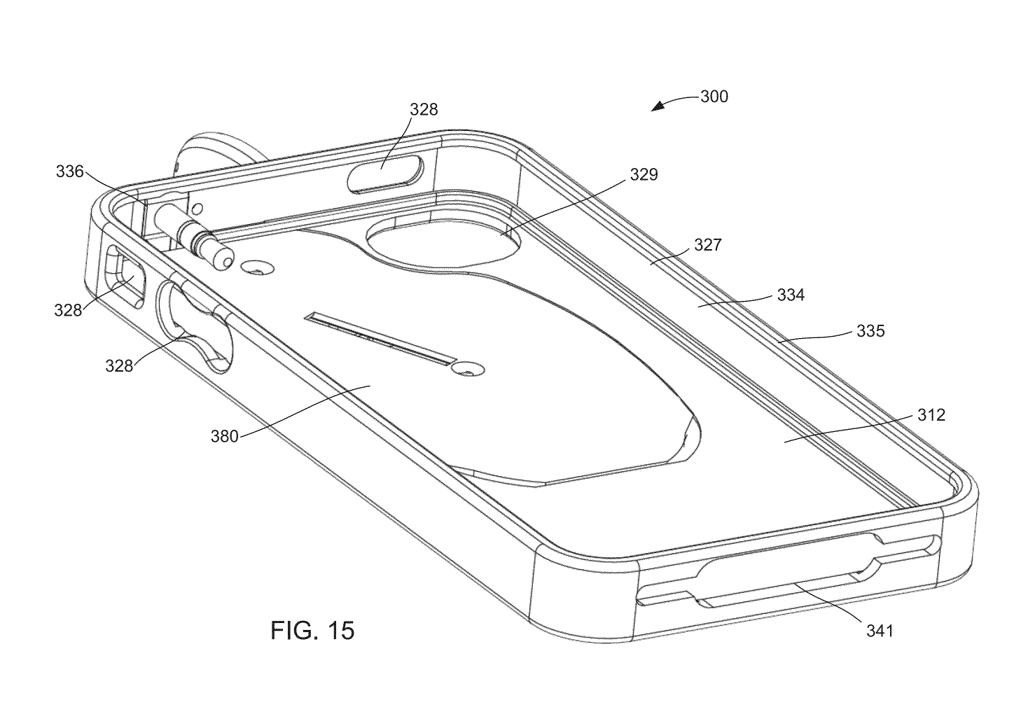

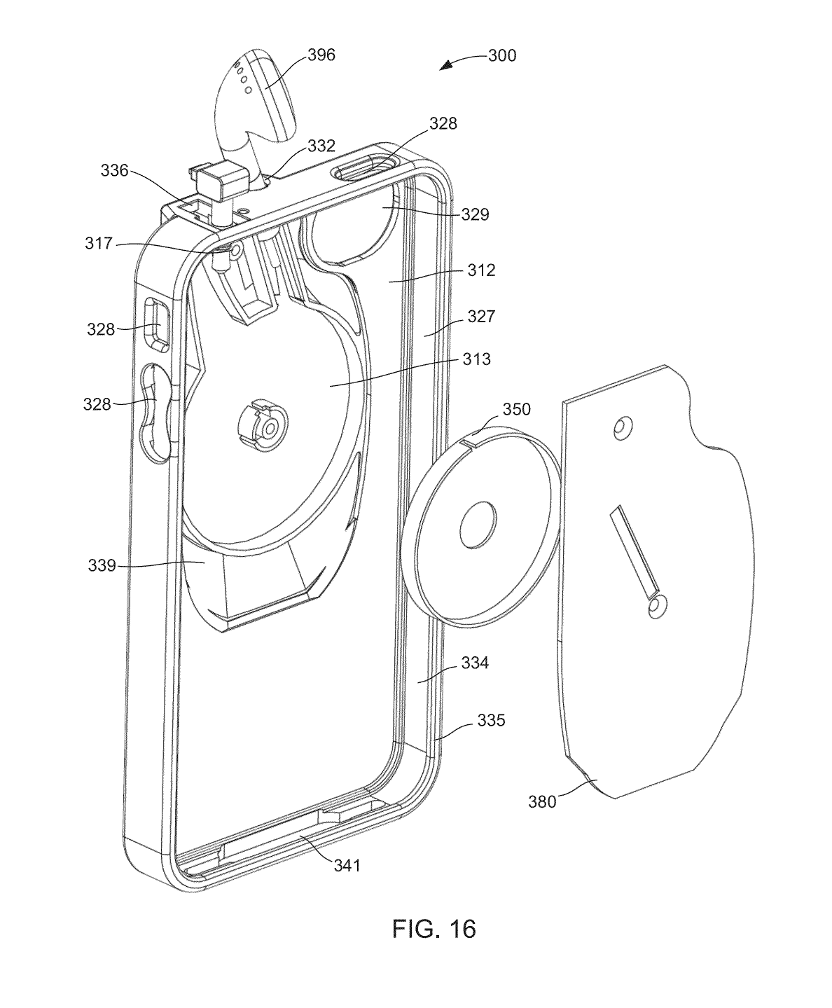

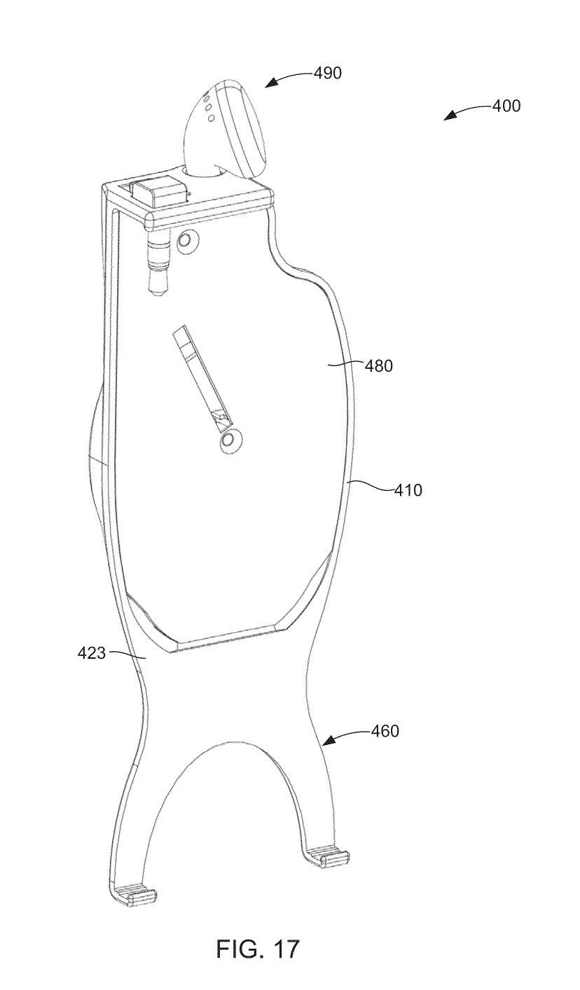

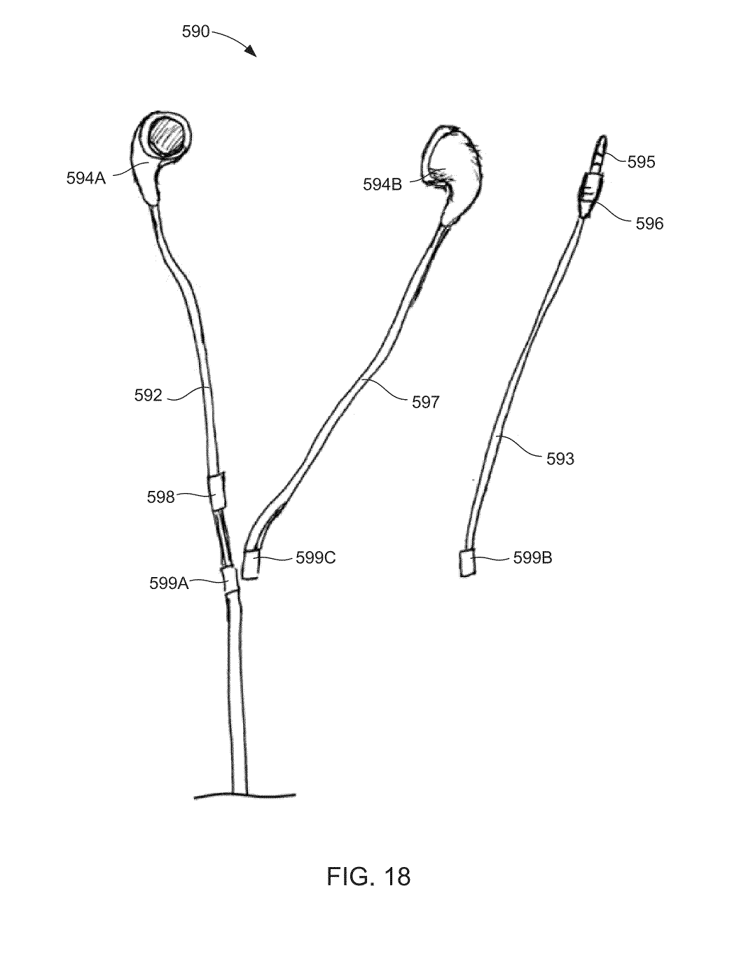

The housing 110 further includes an outer surface 111 and an inner surface 112, as shown in FIGS. 3 and 4. The outer surface 111 can define any suitable shape or configuration. The inner surface 112 can be a substantially flat surface and define a recess 113 including a first channel 114 and a second channel 115. The recess 113 is further defined a recess surface 122 with an inner ring 116 and an outer ring 118 extending substantially away from the recess surface 122. The inner ring 116 and the outer ring 118 receive a portion of the retraction mechanism 150 and the wire assembly 190, as described in further detail herein.

The retraction mechanism 150 includes a retainer 151, a spring 156 (FIG. 5), and a cover 180. The retainer 151 is substantially circular and includes a base 153 and a wall 152. The wall 152 is configured to extend from a surface of the base 153 and defines a passageway 155 configured to receive a portion of the spring 156 and the wire assembly 190. The base 153 defines an opening 154 configured to receive the inner ring 116 and the outer ring 118 of the housing 110. Similarly stated, the retainer 151 can be disposed on the recess surface 122 such that the inner ring 116 and the outer ring 118 extend through the opening 154 defined by the base 153. Therefore, the retainer 151 is configured to be rotatably disposed about the outer ring 118 such that a bottom surface rotates on the recess surface 122. Furthermore, the cover 180 is configured to be coupled to the inner ring 116 to maintain the retainer 151 within the recess 113. More specifically, the cover 180 and the inner ring 116 include an aperture 181 and 117, respectively, configured to receive a mechanical fastener (e.g., a screw), thereby coupling the cover 180 to the inner ring 116.

The wire assembly 190 includes the wire 191 having the first end portion 192 and the second end portion 193. More specifically, the first end portion 192 of the wire 191 is coupled to an audio plug 195 (FIG. 1) and the second end portion 193 is coupled to an earpiece 194 (FIG. 2). The wire 191 is configured to be substantially disposed within the housing 110 when the retractable headset 100 is in a first configuration (FIG. 2) and substantially outside the housing 110 when the retractable headset 100 is in a second configuration (FIG. 6). Expanding further, at least a portion of the wire 191 is disposed within the retainer 151 and configured to rotate the retainer 151 about the outer ring 118 when the wire assembly 190 moves the retractable headset 100 from the first configuration to the second configuration, as describe below.

Referring now to FIG. 5, the spring 156 (e.g., a torsion spring) is disposed within the retainer 151 and includes a first end portion 157 and a second end portion 158. The first end portion 157 is fixedly coupled to the outer ring 118 of the housing 110 via a first passageway 119 and the second end portion 158 is fixedly coupled to the retainer 151 via a passageway 155. Thus, the first end portion 157 of the spring 156 is rigidly coupled to the housing 110 and the second end portion 158 of the spring 156 is rigidly coupled to the retainer 151. Furthermore, the outer ring 118 defines a second passageway 120 configured to receive the first end portion 192 of the wire 191.

As described above, the aperture 136 defined by the upper latch portion 130 (FIGS. 3 and 4), receives the audio plug 195 coupled to the first end portion 192 of the wire 191. The first end portion 192 of the wire 191 extends away from the audio plug 195 within the first channel 114 defined by the inner surface 112 of the housing 110 and into a groove 121 (FIG. 4) defined by the recess surface 122. In this manner, the first end potion 192 of the wire 191 can pass within the groove 121 below the bottom surface of the retainer 151 and pass through the second passageway 120. Therefore, the first end portion 192 can pass through the second passageway 120 without substantially interfering with the rotational motion of the retainer 151.

With a portion of the wire 191 substantially disposed within an annular space 124 defined between the inner ring 116 and the outer ring 118, the wire 191 can substantially loop around the inner ring 116 and pass through the first passageway 119. In this manner, a portion of the wire 191 is configured to coil substantially adjacent to the coils of the spring 156 and pass through the passageway 155 defined by the retainer 151. Furthermore, a portion of the wire 191 outside the retainer 151 can wrap or coil around the outside of the retainer 151, as shown in FIG. 5. With a desired portion of the wire 191 wrapped around the retainer 151, the second end portion 193 of the wire 191 can extend within the second channel 115 defined by the inner surface 112 of the housing 110 to exit the housing 110 via an opening 133 defined by the port 132. In this manner, the second end portion 193 of the wire 191 can be coupled to the earpiece 194. The arrangement of the opening 133 defined by the port 132 is such that the earpiece 194 is maintained substantially outside the housing 110.

As shown in FIG. 6, the retractable headset 100 can be placed in the second configuration by extending the earpiece 194 in a direction substantially away from the port 132. The extending of the earpiece 194 can facilitate the portion of the wire 191 disposed within the housing 110 to unwrap (uncoil) around the wall 152 of the retainer 151. As described above, the unwrapping of the wire 191 (e.g., moving the retractable headset 100 to the second configuration) can rotate the retainer 151 with respect to the outer ring 118. In this manner, the rotational motion of the retainer 151 can place the spring 156 in compression such that the coils of the spring 156 are successively wound tighter as the retainer 151 rotates.

While not shown in FIGS. 1-10, in some embodiments, the retractable headset 100 can include a latch configured to maintain the retractable headset 100 in the second configuration. Expanding further, with the portion of the wire 191 coiled adjacent to spring 156, the compression of spring 156 produces a reaction force within the spring 156 to return to the uncompressed configuration. Thus, the latch can engage the spring 156 and/or the retainer 151 to maintain the spring 156 in the compressed configuration. The latch can be any suitable mechanism configured to maintain the retractable headset 100 in the second configuration. For example, in some embodiments, the latch can be spring driven, triggered (e.g., activated) by a portion of the wire assembly (e.g., a protrusion disposed on a portion of the wire 191).

In some embodiments, the retractable headset 100 can return to the first configuration by further extending the earpiece 194 away from the port 132. For example, in some embodiments, a latch mechanism can maintain the retractable headset 100 in the second configuration and the user can further extend the earpiece 194 such that the latching mechanism is moved to disengage the spring 156 and/or the retainer 151. Therefore, the spring 156 can expand and exert a force on the portion of the wire 191 coiled adjacent to the spring 156. In this manner, a portion of the force of expansion can be applied to the wire 191 such that the second end portion 193 of the wire 191 is retracted toward the port 132. Furthermore, a portion of the force of expansion can be applied to the wire 191 such that a portion of the wire 191 again wraps the wall 152 of the retainer 151, thereby returning the retractable headset 100 to the first configuration.

FIGS. 7-9 illustrate the retractable headset 100 coupled to the mobile device M. As shown in FIG. 7, the lower latch 160 is configured to engage a lower portion of the mobile device M. More specifically, the base 163 and the protrusion 164 of the first latch arm 161 are configured to engage the portion of the mobile device M. Similarly, the base 165 and the protrusion 166 included in the second latch arm 162 are configured to engage the portion of the mobile device M. The upper latch portion 130 includes an inner surface 134 having a protrusion 135 extending away from the inner surface 134 and is configured to engage an upper portion of the mobile device M. Collectively, the protrusion 135 of the upper latch portion 130 and the protrusions 164 and 166 of the lower latch 160 can engage a surface of the mobile device M and define a friction fit. In this manner, protrusions 135, 164, and 166 collectively engage the mobile device M such that the inner surface 112 of the housing 110 is in contact with a back surface of the mobile device M, thereby coupling the retractable headset 100 to the mobile device M.

As shown in FIG. 8, with the retractable headset 100 coupled to the mobile device M, the audio plug 195 coupled to the first end portion 192 of the wire 191 can be inserted into an audio jack J (FIG. 9) defined by the mobile device M. Furthermore, the first end portion 192 of the wire 191 includes a protrusion 196 configured to be disposed within a first portion 137 of the aperture 136 defined by the upper latch portion 130. In this manner, a user can engage the protrusion 196 to move the audio plug 195 substantially out of the audio jack J, thereby placing the retractable headset 100 in a third configuration.

As shown in FIG. 9, when in the third configuration, the protrusion 196 included in the first end portion 191 of the wire 191 can be removed from the first portion 137 of the aperture 136. In this manner, the first end portion 192 of the wire 191 can be configured to be disposed within a second portion 138 of the aperture 136 and the protrusion 196 can be disposed on a top surface 131 of the upper latch portion 130. Expanding further, the second portion 138 of the aperture 136 is substantially smaller than the first portion 137 of the aperture 136 such that when in the third configuration, the protrusion 196 is disposed above the second portion 138 of the aperture 136 (e.g., the protrusion 196 is larger than the second portion 138 of the aperture 136). With the audio plug 195 removed from the audio jack J of the mobile device M, a user can access the audio jack J. For example, in some embodiments, a user can place the retractable headset 100 in the third configuration and connect to the audio jack J of the mobile device M to, for example, an auxiliary input system for a car audio system without decoupling the retractable headset 100 from the mobile device M.

As shown in FIG. 10, a user can place the retractable headset 100 in the third configuration to decouple the retractable headset 100 from the mobile device M. As described above, a user can engage the engagement portion 169 (not shown in FIG. 10) to slide the first attachment arm 167 and the second attachment arm 168 along the engagement surface 126. In some embodiments, the lower latch 160 is pivotally disposed within the lower latch aperture 125 such that as the first attachment arm 167 and the second attachment arm 168 slide along the engagement surface 126, the first latch arm 161 and the second latch arm 162 pivot away from the mobile device M. In this manner, the engagement portion 169 can be engaged to decouple the retractable headset 100 from the mobile device M.

FIGS. 11-13 illustrate a retractable headset 200 according to an embodiment. As shown in FIG. 11, portions of the retractable headset 200 are substantially similar to portions of the retractable headset 100. Therefore, portions of the retractable headset 200 are not described in detail herein and should be considered substantially similar to the retractable headset 100 unless explicitly described otherwise.

The retractable headset 200 includes a housing 210, a retraction mechanism 250 and a wire assembly 290. In some embodiments, the housing 210 can be configured to be coupled to a mobile device in a similar manner as the retraction headset 100 described above. The housing 210 can be any suitable size, shape, or configuration. For example, as shown in FIG. 11-13, the housing 210 can define a substantially oblong shape. Furthermore, the housing 210 can define a relatively small thickness such that, when coupled to the mobile device, the mobile device and the retractable headset 200 collectively define a relatively thin profile (e.g., thickness).

The housing 210 includes an upper latch portion 230 and a bottom portion 223. The upper latch portion 230 includes an aperture 236, configured to receive a first end portion of the wire assembly 190, and a port 232, configured to receive a second end portion of the wire assembly 290. In this manner, the upper latch portion 230 can be coupled to a portion of the mobile device. More specifically, the aperture 236 can receive an audio plug 295 in a similar manner to the aperture 136 defined by the housing 110 of the retractable headset 100. In some embodiments, the port 232 can be an opening defined by a top surface of the upper latch portion 230. In other embodiments, the port 232 can be defined by an annular protrusion extending from the top surface of the upper latch portion 230, such as, for example, the port 132 described with respect to FIG. 4.

The bottom portion 223 defines a lower latch aperture 225 configured to receive a lower latch 260. In some embodiments, the bottom portion 223 and the lower latch 260 are substantially similar to the bottom portion 123 and the lower latch 160 described above with respect to FIGS. 1-10. In other embodiments, the lower latch 260 can be any suitable shape or size configured to be coupled to the bottom portion 223 and facilitate the coupling of the housing 210 to the mobile device (not shown).

The housing 210 further defines a recess 240 configured to allow access to a camera and/or flash included in a mobile device (not shown). In such embodiments, the recess 240 can be any suitable shape, size, or configuration. For example, as shown in FIG. 11, the recess 240 can be a substantially arcuate. In this manner, the recess 240 can be positioned, relative to the mobile device, such that the camera and/or flash of the mobile device are free from obstruction.

The housing 210 further includes an inner surface 212, as shown in FIG. 12. The inner surface 212 can be a substantially flat surface and define a recess 213 including a first channel 214 and a second channel 215. The recess 213 is further defined by a recess surface 222 with an inner ring 216 and an outer ring 218 extending substantially away from the recess surface 222. The inner ring 216 and the outer ring 218 receive a portion of the retraction mechanism 250 and the wire assembly 290, in a similar manner as described above with respect to the retractable headset 100.

The inner surface 212 further defines a void 239. As shown in FIGS. 12 and 13, the void 239 is substantially separated from the recess 213. In other embodiments, the void 239 and the recess 213 can be a substantially continuous recess defined by the inner surface 212. Furthermore, the inner surface 212 can define any suitable recess, void, extrusion, and/or the like. In some embodiments, the void 239 can be configured to reduce the material usage and/or the weight of the retraction headset 200.

As shown in FIG. 13, the retractable headset 200 includes a cover 280. The cover 280 is configured to be coupled to the inner surface 213 and substantially cover the retraction mechanism 250 and at least a portion of the wire assembly 290. More specifically, the cover 280 includes apertures 281 that can receive mechanical fasteners (e.g., screws) configured to be inserted into apertures 217 defined by the inner surface 213, thereby coupling the cover 280 to the inner surface 213.

The cover 280 can be any suitable size, shape, or configuration. For example, as shown in FIG. 13, the cover 280 defines a shape similar to the housing 210. In this manner, when the cover 280 is coupled to the housing 210, the cover 280 can enclose the void 239, the recess 213, the first channel 214, and the second channel 215. Furthermore, the cover 280 defines a recess 282 that can be similar in form and function as the recess 240 defined by the housing 210.

FIGS. 14-16 illustrate a retractable headset 300 according to an embodiment. As shown, portions of the retractable headset 300 are substantially similar to portions of the retractable headset 200. Therefore, portions of the retractable headset 300 are not described in detail herein and should be considered substantially similar to the retractable headset 200 unless explicitly described otherwise.

The retractable headset 300 includes a housing 310, a retraction mechanism 350 and a wire assembly 390. The housing 310 can be any suitable size, shape, or configuration. For example, as shown in FIGS. 14 and 15, the housing 310 is substantially rectangular and includes an outer surface 311 and an inner surface 312. Furthermore, the housing includes a set of walls 327 extending perpendicularly from the inner surface 312. The walls 327 define a port 332, an audio plug aperture 336, a set of button apertures 338, a camera aperture 339, and a plug aperture 341.

The port 332 and the audio plug aperture 336 can be substantially similar to the port 232 and the aperture 236 described above with respect to the retractable headset 200 of FIGS. 11-13. The button apertures 338 are configured to receive various buttons included in a mobile device. While shown in FIGS. 14-16 as being in specific locations, the button apertures 338 can be in any suitable position such that the button apertures 338 receive a set of buttons included in a mobile device. Similarly, the camera aperture 339 can be in any suitable position, relative to the mobile device, such that a camera and/or flash are substantially free from obstruction. The plug aperture 341 (FIG. 15) is configured to facilitate the insertion of a plug (e.g., a power cord, data cord, and/or the like) into a mobile device when the retractable headset 300 is coupled to the mobile device. Expanding further, the plug aperture 341 can be any suitable size, shape, or configuration and can be positioned at any location along the walls 327 of the housing 310 such that a receiving port of the mobile device is free from obstruction. Furthermore, in some embodiments, the plug aperture 341 can include portions configured to receive other portions of the mobile device, such as, for example, speakers.

The inner surface 313 of the housing 310 (FIG. 16) defines a recess 313 and a void 339 that are substantially similar in form and function to the recess 213 and the void 239 shown with respect to FIGS. 12 and 13. Similarly, the retractable headset 300 includes a cover 380 and the refraction mechanism 350 that are substantially similar in form and function to the cover 280 and the retraction mechanism 250 included in the retractable headset 200. Therefore, the recess 313, the void 339, the cover 380, and the retraction mechanism 350 are not described in further detail herein.

As shown in FIGS. 15 and 16, the walls 327 of the housing 310 include an inner surface 334 with a protrusion 335 extending away from the inner surface 334. The arrangement of the inner surface 334 and the protrusion 335 allow the walls 327 to engage a mobile device such as to couple the retractable headset 300 to the mobile device (not shown). More specifically, when coupled to the mobile device the protrusion 335 can engage a surface of the mobile device and define a friction fit. In this manner, the walls 327 (e.g., the inner surface 334 and the protrusion 335) engage the mobile device such that the inner surface 312 of the housing 310 is in contact with a back surface of the mobile device, thereby coupling the retractable headset 300 to the mobile device.

While embodiments described herein include independent portions coupled together, in some embodiments, any portions described herein can be monolithically formed. For example, while the lower latch 160 (shown with respect to FIGS. 1-10) is described as being coupled to the housing 110, in some embodiments, a lower latch can be monolithically formed with a housing. By way of example, FIG. 17 illustrates a retractable headset 400 that includes a lower latch 460 that is monolithically formed with the housing 410. In this manner, the retractable headset 400 can be coupled to a mobile device and can function similarly to the retractable headset 100 described above with respect to FIGS. 1-10.

While embodiments herein describe a specific variety of headphones (e.g., wire assembly), any of the embodiments described herein can include any suitable set of headphones. For example, FIG. 18 illustrates a wire assembly 500 included in a retractable headset (not shown in FIG. 18), according to an embodiment. The wire assembly 590 includes a first portion 591, a second portion 592, and a third portion 597. The first portion 592 includes an earpiece 594A that can be substantially similar to the earpiece 194 included in the retractable headset 100, described with respect to FIGS. 1-10. Additionally, the first portion 592 includes a microphone 598 and a connector 599A. The microphone 598 is configured to function similarly to known microphones and, as such, the wire assembly 590 is configured to convey dictation from a user to a mobile device.

The second portion 593 includes an audio plug 595, a protrusion 596, and a connector 599B. The audio plug 595 and the protrusion 596 can be substantially similar to the audio plug 195 and the protrusion 196 and can be configured to engage an audio jack of a mobile device. The third portion 597 includes a second earpiece 594B and a third connector 599C. The second earpiece 594B can be configured to provide a stereo sound to the user of the wire assembly 590.

The arrangement of the connectors 599A, 599B, and 599C can be such that the first portion 592, the second portion 593, and the third portion 597 can be removably coupled together. Expanding further, with the connector 599A of the first portion 592 coupled to the connector 599B of the second portion 593, the wire assembly 590 can be configured to engage the mobile device to function as a headset. More specifically, in this configuration, the wire assembly 590 can function to transmit sound from the mobile device to the earpiece 594A and/or from the microphone 598 to the mobile device. Optionally, the connector 599C of the third portion 597 can be coupled to the connector 599A of the first portion 592 and/or the connector 599B of the second portion 593 to provide a user of the wire assembly 590 with stereo sound (e.g., via the first earpiece 594A and the second earpiece 594B). Thus, in some embodiments, the user of the wire assembly 590 (and the mobile device) can disconnect the second portion 592 and/or the third portion 597 from the first portion 592 for storage, when done using the wire assembly 590.

While various embodiments of the invention have been described above, it should be understood that they have been presented by way of example only, and not limitation. Where methods described above indicate certain events occurring in certain order, the ordering of certain events may be modified. Additionally, certain of the events may be performed concurrently in a parallel process when possible, as well as performed sequentially as described above. Although various embodiments have been described as having particular features and/or combinations of components, other embodiments are possible having a combination of any features and/or components from any of embodiments where appropriate.

1. An apparatus, comprising:
a housing configured to be coupled to a mobile device;
a retainer rotatably coupled to the housing;
a spring coupled to the retainer;
a wire coiled coincidentally with the spring, at least a portion of the wire engaging substantially a length of the spring when in a coiled configuration.

2. The apparatus of claim 1, wherein the retainer defines a passageway configured to receive at least a portion of the wire, the portion of the wire coupled to an audio plug.

3. The apparatus of claim 1, wherein the retainer is configured to rotate with respect to the housing when the wire is moved between the coiled configuration and an extended configuration, the wire being substantially maintained within the housing in the coiled configuration and substantially outside the housing in the extended configuration.

4. The apparatus of claim 1, wherein the spring is rigidly coupled to the retainer.

5. The apparatus of claim 1, wherein an end of the spring is coupled to an outer wall of the retainer, another end of the spring is coupled to an inner portion of the retainer.

6. The apparatus of claim 1, further comprising a cap coupled to the retainer, the cap configured to maintain the wire and the spring in the housing.

7. The apparatus of claim 1, further comprising an audio plug coupled to an end of the wire, the housing being removably coupled to the audio plug.

8. The apparatus of claim 1, further comprising an audio plug, the audio plug being removably coupled to the housing while fixedly coupled to the wire.

9. The apparatus of claim 1, wherein the housing includes a first portion and a second portion, the second portion being removably coupled to the first portion.

10. An apparatus, comprising:
a housing having
a first portion configured to be coupled to a body of a mobile device;
a second portion configured to be coupled to an audio jack of the mobile device, the second portion removably coupled to the first portion;
a retraction mechanism coupled to the housing and including
a retainer;
a spring having a first end and a second end, the spring being coupled to the retainer;
a cover configured to maintain the spring within the retainer
a headset wire having a first end and a second end, the first end of the headset wire being coupled to an audio plug, the second end of the headset wire being coupled to an ear piece, the headset wire being at least partially coiled with the spring.

11. The apparatus of claim 10, wherein the apparatus has a first configuration in which the headset wire is substantially coiled coincidentally with the spring and a second configuration in which the headset wire is spaced apart from the spring.

12. The apparatus of claim 10, wherein the first portion of the housing defines a groove through which at least a portion of the headset wire is configured to extend, the portion of the headset wire being adjacent to the audio plug.

13. The apparatus of claim 10, wherein the first portion of the housing is one of removably or piviotally coupled to the second portion of the housing.
